(19) United States
(12) Patent Application Publication
(10) Pub. No.: US 2022/0155685 A1
(43) Pub. Date: May 19, 2022

(54) PHOTOSENSITIVE RESIN COMPOSITION AND CURED FILM PREPARED THEREFROM

(71) Applicant: ROHM AND HAAS ELECTRONIC MATERIALS KOREA LTD., Chungcheongnam-do (KR)

(72) Inventors: Jin Kwon, Gyeonggi-do (KR); Kyu-Cheol Lee, Gyeonggi-do (KR)

(21) Appl. No.: 17/525,401

(22) Filed: Nov. 12, 2021

(30) Foreign Application Priority Data
Nov. 19, 2020 (KR) 10-2020-0155359

(51) Int. Cl. G03F 7/038; G03F 7/40; G03F 7/32; G03F 7/004

(52) U.S. Cl. CPC G03F 7/0382; G03F 7/0045; G03F 7/322; G03F 7/40

(57) ABSTRACT

The present invention provides a photosensitive resin composition capable of forming a cured film having excellent resolution and chemical resistance upon curing at low temperatures and to a cured film prepared therefrom. In the photosensitive resin composition of the present invention, the first copolymer and the second copolymer are used as a binder to introduce appropriate amounts of a succinate group and an epoxy group to the composition. Thus, it is possible to prepare a cured film that can be sufficiently cured even at low temperatures by enhancing the degree of curing and that has excellent resolution through the control of the developability and enhancements in the crosslinking reaction. Further, the composition has enhanced chemical resistance to chemical solvents or cleaning solvents, whereby deformation of the cured film can be prevented.

### TECHNICAL FIELD

The present invention relates to a photosensitive resin composition capable of forming a cured film having excellent resolution and chemical resistance upon curing at low temperatures and to a cured film prepared therefrom.

### BACKGROUND ART

Photosensitive resin compositions are widely used in LCDs, OLEDs, and quantum dot-based display devices. OLEDs and quantum dot-based display devices require a composition that can be cured at low temperatures since they are fabricated at low temperatures.

For example, an LCD is composed of an upper substrate, a lower substrate, and liquid crystals interposed between the substrates. If necessary, a touch screen panel (TSP) or the like may be connected to the upper substrate. In general, a TSP is fabricated after the assembly step in which a color filter and a thin film transistor (TFT) are combined. In order to minimize the impact on the lower panel, which has already been fabricated, a composition must be cured at a low temperature to prepare a cured film. However, a composition would not be sufficiently crosslinked when cured at a low temperature, failing to form a cured film, or the strength thereof is not sufficient even though it is formed. Thus, there is a need for a composition that can be cured at low temperatures.

In addition, if a metal patterning process is carried out after the formation of a cured film, the chemical solvent used for patterning or the cleaning solvent used after patterning may affect the cured film already formed, so that it swells or the film thickness changes. Thus, the composition is also required to have chemical resistance.

In this connection, a technique for preparing a cured film by curing a composition comprising an acrylate-based resin as a binder at a low temperature has been known in the relevant art (see Korean Laid-open Patent Publication No. 2010-0029479). But it is not sufficient to satisfy the chemical resistance. In addition, since the binder substantially implemented in the above patent has a high acid value, there is a limitation in terms of shelf-life (i.e., the temporal stability).

### PRIOR ART DOCUMENT

### Patent Document

(Patent Document 1) Korean Laid-open Patent Publication No. 2010-0029479

### DETAILED DESCRIPTION OF THE INVENTION

### Technical Problem

An object of the present invention is to provide a photosensitive resin composition that can be sufficiently cured even at low temperatures with excellent developability, resolution, and chemical resistance, and a cured film prepared therefrom.

### Solution to the Problem

The present invention provides a photosensitive resin composition, which comprises (A) a first copolymer comprising (a1) a structural unit derived from an ethylenically unsaturated carboxylic acid, an ethylenically unsaturated carboxylic anhydride, or a combination thereof, (a2) a structural unit derived from an ethylenically unsaturated compound containing an alicyclic epoxy group; (a3) a structural unit derived from an ethylenically unsaturated compound containing an acyclic epoxy group; and (a4) a structural unit derived from an ethylenically unsaturated compound different from (a1) to (a3); (B) a second copolymer comprising (b1) a repeat unit represented by the following Formula 1 and comprising at least one selected from the group consisting of (b2) a repeat unit represented by the following Formula 2, (b3) a repeat unit represented by the following Formula 3, and (b4) a repeat unit different from the repeat units (b1) to (b3); (C) a photopolymerizable compound; (D) a photopolymerization initiator; and (E) a solvent.

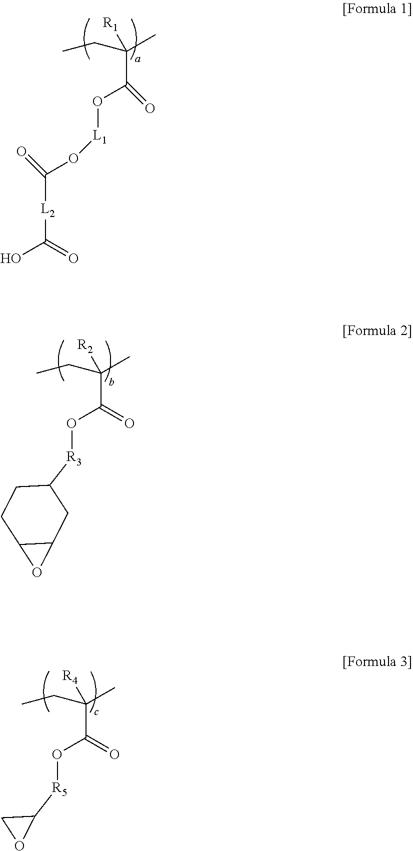

In the above formulae, R₁ is hydrogen or substituted or unsubstituted C₁₋₂₀ alkyl, L₁ and L₂ are each independently a substituted or unsubstituted C₁₋₁₀ alkylene or a substituted or unsubstituted C₆₋₂₀ arylene, R₂ and R₄ are each independently hydrogen or C₁₋₈ alkyl, R₃ and R₅ are each independently C₁₋₄ alkylene, and a, b, and c are each independently an integer of 1 to 100.

In addition, the present invention provides a cured film formed from the photosensitive resin composition.

### Advantageous Effects of the Invention

In the photosensitive resin composition of the present invention, the first copolymer and the second copolymer are used as a binder to introduce appropriate amounts of a succinate group and an epoxy group to the composition. Thus, it is possible to prepare a cured film that can be sufficiently cured even at low temperatures by enhancing the degree of curing and that has excellent resolution through the control of the developability and enhancements in the crosslinking reaction. Further, the composition has enhanced chemical resistance to chemical solvents or cleaning solvents, whereby deformation of the cured film can be prevented.

### BEST MODE FOR CARRYING OUT THE INVENTION

Hereinafter, the present invention will be described in more detail.

The present invention is not limited to those described below. Rather, it can be modified into various forms as long as the gist of the invention is not altered.

Throughout the present specification, when a part is referred to as “comprising” an element, it is understood that other elements may be comprised, rather than other elements are excluded, unless specifically stated otherwise. In addition, all numbers and expressions relating to quantities of components, reaction conditions, and the like used herein are to be understood as being modified by the term “about” unless specifically stated otherwise.

The present invention provides a photosensitive resin composition, which comprises (A) a first copolymer, (B) a second copolymer, (C) a photopolymerizable compound, (D) a photopolymerization initiator, and (E) a solvent.

The photosensitive resin composition may optionally further comprise (F) an adhesion supplement and/or (G) a surfactant.

As used herein, the term “(meth)acryl” refers to “acryl” and/or “methacryl,” and the term “(meth)acrylate” refers to “acrylate” and/or “methacrylate.” The weight average molecular weight (g/mole or Da) of each component as described below is measured by gel permeation chromatography (GPC, eluent: tetrahydrofuran) referenced to a polystyrene standard.

(A) First Copolymer

The present invention comprises the following first copolymer (A) as a binder. The first copolymer (A) comprises (a1) a structural unit derived from an ethylenically unsaturated carboxylic acid, an ethylenically unsaturated carboxylic anhydride, or a combination thereof, (a2) a structural unit derived from an ethylenically unsaturated compound containing an alicyclic epoxy group; (a3) a structural unit derived from an ethylenically unsaturated compound containing an acyclic epoxy group; and (a4) a structural unit derived from an ethylenically unsaturated compound different from (a1) to (a3).

As the first copolymer comprises the above structural units, in particular, alicyclic and acyclic epoxy groups in the structure together, a cured film when formed can serve as a base upon the coating of the composition and as a structure for achieving the final pattern.

(a1) Structural Unit Derived from an Ethylenically Unsaturated Carboxylic Acid, an Ethylenically Unsaturated Carboxylic Anhydride, or a Combination Thereof.

The structural unit (a1) in the present invention may be derived from an ethylenically unsaturated carboxylic acid, an ethylenically unsaturated carboxylic anhydride, or a combination thereof.

The ethylenically unsaturated carboxylic acid, the ethylenically unsaturated carboxylic anhydride, or a combination thereof is a polymerizable unsaturated monomer containing at least one carboxyl group in the molecule. It may be at least one selected from an unsaturated monocarboxylic acid such as (meth)acrylic acid, crotonic acid, α-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; an unsaturated polycarboxylic acid having three or more valences and an anhydride thereof; and a mono[(meth)acryloyloxyalkyl] ester of a polycarboxylic acid of divalence or more such as mono[2-(meth)acryloyloxyethyl] phthalate, and the like. But it is not limited thereto. Preferably, it may be (meth)acrylic acid from the viewpoint of developability.

The amount of the structural unit (a1) may be 5 to 50% by mole, 10 to 40% by mole, 10 to 30% by mole, 10 to 25% by mole, 15 to 30% by mole, or 15 to 25% by mole, based on the total number of moles of the structural units constituting the first copolymer (A). Within the above range, it is possible to attain a pattern formation of a film while maintaining favorable developability.

(a2) Structural Unit Derived from an Ethylenically Unsaturated Compound Containing an Alicyclic Epoxy Group

The structural unit (a2) in the present invention may be derived from an unsaturated monomer containing an alicyclic epoxy group.

Examples of the unsaturated monomer containing an alicyclic epoxy group include 2,3-epoxycyclopentyl (meth)acrylate, 3,4-epoxycyclohexyl (meth)acrylate, 3,4-epoxycyclohexylmethyl (meth)acrylate, N-(4-(2,3-epoxypropoxy)-3,5-dimethylbenzyl) acrylamide, N-(4-(2,3-epoxypropoxy)-3,5-dimethylphenylpropyl) acrylamide, or a mixture thereof. Preferred are 3,4-epoxycyclohexyl (meth)acrylate, 3,4-epoxycyclohexylmethyl (meth)acrylate, or a mixture thereof from the viewpoint of storage stability at room temperature and solubility.

The structural unit (a2) controls the pattern flowability of the composition during low-temperature curing, thereby enabling the implementation of a pattern on the cured film. In addition, it enables the formation of a structure through a crosslinking reaction, that is, the formation of a cured film having sufficient film strength. Further, it can impart chemical resistance to the cured film.

The amount of the structural unit (a2) may be 1 to 30% by mole, 1 to 25% by mole, 1 to 20% by mole, 5 to 25% by mole, or 10 to 20% by mole, based on the total number of moles of the structural units constituting the first copolymer. Within the above range, the storage stability of the composition may be maintained, and the pattern forming capability and film retention rate may be enhanced.

(a3) Structural Unit Derived from an Ethylenically Unsaturated Compound Containing an Acyclic Epoxy Group

The structural unit (a3) in the present invention may be derived from an unsaturated monomer containing an acyclic epoxy group.

Examples of the unsaturated monomer containing an acyclic epoxy group include glycidyl (meth)acrylate, 4-hydroxybutyl acrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, α-ethyl glycidyl acrylate, α-n-propyl glycidyl acrylate, α-n-butyl glycidyl acrylate, allyl glycidyl ether, 2-methylallyl glycidyl ether, and a mixture thereof. Preferred is glycidyl (meth)acrylate from the viewpoint of storage stability at room temperature and solubility.

As the first copolymer comprises the structural unit (a3) and the structural unit (a2) together, it is possible to control the pattern flowability of the composition during low-temperature curing, thereby enabling the implementation of a pattern on the cured film and the formation of a cured film having sufficient film strength. In addition, it can impart chemical resistance to the cured film, as well as enhance the bonding strength with the lower substrate.

The amount of the structural unit (a3) may be 1% by mole to 30% by mole, 1% by mole to 25% by mole, 1% by mole to 20% by mole, 5% by mole to 25% by mole, 5% by mole to 20% by mole, or 5% by mole to 10% by mole, based on the total number of moles of the structural units constituting the first copolymer. Within the above range, the storage stability of the composition may be maintained, and the pattern forming capability and film retention rate may be enhanced.

As the first copolymer comprises the structural units (a2) and (a3) together, it is possible to secure shelf-life at room temperature and chemical resistance and to maintain the desired developability, thereby obtaining excellent resolution. If the first copolymer comprises any one of the structural unit (a2) and the structural unit (a3), for example, if it comprises the structural unit (a3) alone, the shelf-life at room temperature and chemical resistance may be deteriorated, and the developability may be lowered, resulting in a deterioration in the resolution.

The total content of the structural units (a2) and (a3) may be 10 to 60% by mole, 15 to 45% by mole, 15 to 35% by mole, 15 to 30% by mole, 20 to 30% by mole, 25 to 35% by mole, 22 to 35% by mole, or 25 to 30% by mole, based on the total number of moles of the structural units constituting the first copolymer. Within the above range, the storage stability of the composition is maintained, and the film retention rate is enhanced.

In addition, the molar ratio of the structural units (a2):(a3) may be 50 to 99:50 to 1, 50 to 95:50 to 5, 50 to 90:50 to 10, 50 to 80:50 to 20, 50 to 70:50 to 30, 60 to 90:40 to 10, 70 to 90:30 to 10, or 60 to 80:40 to 20. Within the above range, it is possible to achieve excellent shelf-life at room temperature, thermal resistance, and chemical resistance, and the pattern forming capability is enhanced.

(a4) Structural Unit Derived from an Ethylenically Unsaturated Compound Different from (a1) to (a3)

The structural unit (a4) in the present invention may be derived from an ethylenically unsaturated compound different from the structural units (a1) to (a3).

The ethylenically unsaturated compound different from the structural units (a1) to (a3) may be an aromatic ring-containing unsaturated compound, an unsaturated carboxylic acid ester compound, an N-vinyl tertiary amine compound containing N-vinyl, an unsaturated ether compound, an unsaturated imide compound, or a mixture thereof.

Examples of the ethylenically unsaturated compound containing an aromatic ring include phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tribromophenyl (meth)acrylate, styrene, methylstyrene, dimethylstyrene, trimethylstyrene, ethylstyrene, diethylstyrene, triethylstyrene, propylstyrene, butylstyrene, hexylstyrene, heptylstyrene, octylstyrene, fluorostyrene, chlorostyrene, bromostyrene, iodostyrene, methoxystyrene, ethoxystyrene, propoxystyrene, p-hydroxy-α-methylstyrene, acetylstyrene, vinyltoluene, divinylbenzene, vinylphenol, o-vinylbenzyl methyl ether, m-vinylbenzyl methyl ether, and p-vinylbenzyl methyl ether.

Examples of the unsaturated carboxylic acid ester compound include methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate.

Examples of the N-vinyl tertiary amine compound containing N-vinyl include N-vinyl pyrrolidone, N-vinyl carbazole, and N-vinyl morpholine.

Examples of the unsaturated ether compound include vinyl methyl ether and vinyl ethyl ether.

Examples of the unsaturated imide compound include N-phenylmaleimide, N-(4-chlorophenyl)maleimide, N-(4-hydroxyphenyl)maleimide, and N-cyclohexylmaleimide.

The amount of the structural unit (a4) may be 5 to 70% by mole, 10 to 65% by mole, 20 to 60% by mole, 30 to 60% by mole, 40 to 60% by mole, 45 to 60% by mole, or 45 to 55% by mole, based on the total number of moles of the structural units constituting the first copolymer. Within the above range, it is possible to control the reactivity of the first copolymer and to increase the solubility thereof to an aqueous alkaline solution, so that the coatability of the photosensitive resin composition can be remarkably enhanced.

The first copolymer (A) used in the present invention may be synthesized by copolymerization known in the art. Specifically, the first copolymer (A) may be prepared by charging to a reactor a radical polymerization initiator, a solvent, and monomer compounds capable of deriving the above structural units, followed by charging nitrogen thereto and slowly stirring the mixture for polymerization.

The radical polymerization initiator may be an azo compound such as 2,2′-azobisisobutyronitrile, 2,2′-azobis(2,4-dimethylvaleronitrile), and 2,2′-azobis(4-methoxy-2,4-dimethylvaleronitrile); or benzoyl peroxide, lauryl peroxide, t-butyl peroxypivalate, 1,1-bis(t-butylperoxy)cyclohexane, or the like, but it is not limited thereto. The radical polymerization initiator may be used alone or in combination of two or more.

The solvent may be any solvent commonly used in the preparation of a copolymer. It may be, for example, methyl 3-methoxypropionate (MMP) in view of the polarity and solubility of the monomer compounds capable of deriving the structural units.

The first copolymer (A) may have a weight average molecular weight (Mw) of 500 to 50,000 Da, 1,000 to 50,000 Da, 1,000 to 40,000 Da, 1,000 to 30,000 Da, 1,000 to 10,000 Da, 3,000 to 10,000 Da, 5,000 to 10,000 Da, or 5,000 to 8,000 Da. Within the above range, the adhesiveness to a substrate is excellent, the physical and chemical properties are good, and the viscosity is maintained at a proper level.

In addition, the first copolymer (A) may have an acid value of 10 to 40 mg KOH/g, 15 to 50 mg KOH/g, 20 to 40 mg KOH/g, 15 to 30 mg KOH/g, or 20 to 30 mg KOH/g. Within the above range, the shelf-life of the photosensitive resin composition can be further enhanced.

The content of the first copolymer (A) may be 1 to 80% by weight, 5 to 75% by weight, 10 to 65% by weight, or 15 to 60% by weight, based on the total weight of the photosensitive resin composition on the basis of solids content. The solids content refers to the content of the entire composition excluding the balanced amount of solvents. Within the above range, it is possible to form a cured film having sufficient film strength and excellent bonding strength to a substrate, as well as to render good pattern development upon development and enhanced properties such as film retention rate and chemical resistance.

(B) Second Copolymer

The present invention comprises the following second copolymer (B) as a binder. The second copolymer (B) comprises (b1) a repeat unit represented by the following Formula 1 and comprises at least one selected from the group consisting of (b2) a repeat unit represented by the following Formula 2, (b3) a repeat unit represented by the following Formula 3, and (b4) a repeat unit different from the repeat units (b1) to (b3).

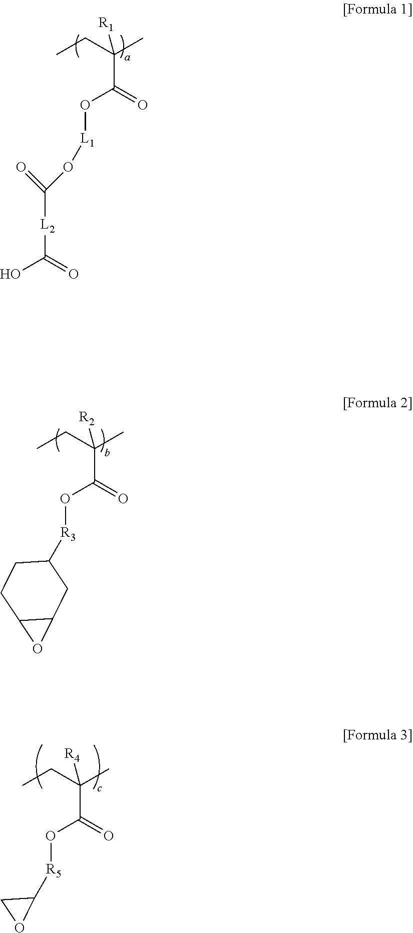

In the above formulae, R₁ is hydrogen or substituted or unsubstituted C₁₋₂₀ alkyl, L₁ and L₂ are each independently a substituted or unsubstituted C₁₋₁₀ alkylene or a substituted or unsubstituted C₆₋₂₀ arylene, R₂ and R₄ are each independently hydrogen or C₁₋₈ alkyl, R₃ and R₅ are each independently C₁₋₄ alkylene, and a, b, and c are each independently an integer of 1 to 100.

According to an embodiment, the second copolymer may comprise a combination of the repeat units (b1), (b2), and (b4).

According to an embodiment, the second copolymer may comprise a combination of the repeat units (b1), (b3), and (b4).

According to an embodiment, the second copolymer may comprise a combination of the repeat units (b1), (b2), (b3), and (b4).

As the second copolymer comprises the above repeat units, in particular, a succinate group and an epoxy group in the structure together, it is possible to implement a pattern of a cured film and to further enhance the chemical resistance while maintaining film strength.

(b1) Repeat Unit Represented by Formula 1

The second copolymer (B) may comprise (b1) a structural unit represented by the following Formula 1. The repeat unit (b1) serves to control the developability in the composition, thereby enhancing the resolution and chemical resistance

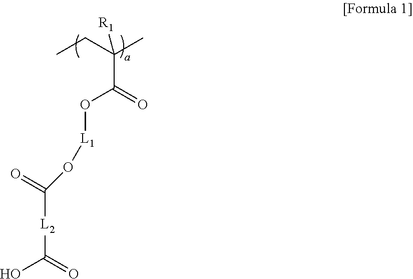

The definitions of R₁, L₁, L₂, and a are the same as described above.

Specifically, R₁ is hydrogen or unsubstituted C₁₋₁₀ alkyl, L₁ and L₂ are each independently substituted or unsubstituted C₁₋₁₀ alkylene, and a is an integer of 1 to 80.

More specifically, R₁ is hydrogen or unsubstituted C₁₋₈ alkyl, Lₜ and L₂ are each independently unsubstituted C₁₋₆ alkylene, and a is an integer of 1 to 50.

In the present invention, the repeat unit (b1) may be derived from an ethylenically unsaturated compound containing an acid group. Specifically, it may be derived from a long-chain compound containing a carboxyl group. More specifically, it may be derived from a succinate acrylate-based compound.

Examples of the succinate acrylate-based compound include 2-(meth)acryloyloxyethyl succinate, mono-2-(meth)acryloylethyl succinate, and a mixture thereof.

The content of the repeat unit (b1) may be 1 to 20% by mole, 1 to 18% by mole, I to 15% by mole, 3 to 20% by mole, 3 to 18% by mole, 5 to 18% by mole, or 5 to 15% by mole, based on the total number of moles of the repeat units constituting the second copolymer (B). In addition, the content of the repeat unit (b1) may be 1 to 15% by weight or 2 to 10% by weight based on the total weight of the first copolymer (A) and the second copolymer (B).

Within the above range, the succinate group is present in the composition in an appropriate amount, whereby it is possible to improve the solubility of the composition to prevent the delamination of a pattern and to further enhance the chemical resistance while maintaining excellent resolution. If the amount is less than the above range, the developability is deteriorated, thereby impairing the resolution. If the amount is greater than the above range, the polymerization of the second copolymer may be hardly performed, or the composition may be developed excessively, thereby reducing the degree of curing when a cured film is formed.

(b2) Repeat Unit Represented by Formula 2

The second copolymer (B) may comprise (b2) a structural unit represented by the following Formula 2. The repeat unit (b2) is introduced into the composition together with the repeat unit (b3) to be described below to control the pattern flowability of the composition during low-temperature curing, thereby enabling the implementation of a pattern on the cured film. In addition, it enables the formation of a structure through a crosslinking reaction, that is, the formation of a cured film having sufficient film strength. Further, it can impart chemical resistance to the cured film.

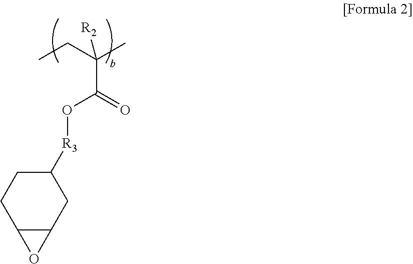

The definitions of R₂, R₃, and b are the same as described above.

Specifically, R₂ is hydrogen or unsubstituted C₁₋₈ alkyl, R₃ is C₁₋₃ alkylene, and b is an integer of 1 to 80.

More specifically, R₂ is hydrogen or unsubstituted C₁₋₅ alkyl, R₃ is C₁₋₃ alkylene, and b is an integer of 1 to 50.

The repeat unit (b2) represented by the above Formula 2 may be derived from an ethylenically unsaturated compound containing an alicyclic epoxy group.

The ethylenically unsaturated compound containing an alicyclic epoxy group may be the same as the compound deriving the structural unit (a2) of the first copolymer (A), but it is not limited thereto. For example, it may be 2,4-epoxycyclohexylmethyl acrylate, 3,4-epoxycyclohexylmethyl acrylate, or 3,4-epoxycyclohexylmethyl methacrylate.

The content of the repeat unit (b2) may be 1 to 30% by mole, 10 to 30% by mole, 10 to 28% by mole, or 10 to 25% by mole, based on the total number of moles of the repeat units constituting the second copolymer (B). In addition, the content of the repeat unit (b2) may be 1 to 30% by weight, 1 to 25% by weight, or 2 to 20% by weight, based on the total weight of the first copolymer (A) and the second copolymer (B). In addition, the total content of the repeat unit (b2) and the structural unit (a2) may be 5 to 30% by weight, 5 to 25% by weight, or 7 to 25% by weight, based on the total weight of the first copolymer (A) and the second copolymer (B). Within the above range, the storage stability of the composition is maintained, and the film retention rate is enhanced.

(b3) Repeat Unit Represented by Formula 3

The second copolymer (B) may comprise (b3) a structural unit represented by the following Formula 3.

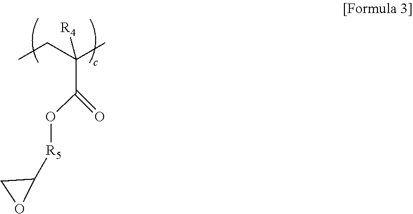

The definitions of R₄, R₅, and c are the same as described above.

Specifically, R₄ is hydrogen or unsubstituted C₁₋₈ alkyl, R₅ is C₁₋₃ alkylene, and c is an integer of 1 to 80.

More specifically, R₄ is hydrogen or unsubstituted C₁₋₅ alkyl, R₅ is C₁₋₃ alkylene, and c is an integer of 1 to 50.

The repeat unit (b3) represented by the above Formula 3 may be derived from an ethylenically unsaturated monomer containing an acyclic epoxy group. The ethylenically unsaturated monomer containing an acyclic epoxy group may be the same as the compound deriving the structural unit (a3) of the first copolymer (A), but it is not limited thereto. For example, it may be glycidyl (meth)acrylate, 4-hydroxybutyl acrylate glycidyl ether, or a mixture thereof.

The content of the repeat unit (b3) may be 1 to 30% by mole, 1 to 20% by mole, 1 to 10% by mole, 10 to 30% by mole, 5 to 20% by mole, 5 to 15% by mole, or 8 to 12% by mole, based on the total number of moles of the repeat units constituting the second copolymer (B). In addition, the content of the repeat unit (b3) may be 1 to 10% by weight, 1 to 7% by weight, or 2 to 6% by weight, based on the total weight of the first copolymer (A) and the second copolymer (B). In addition, the total content of the repeat unit (b3) and the structural unit (a3) may be 1 to 15% by weight, 1 to 13% by weight, or 2 to 11% by weight, based on the total weight of the first copolymer (A) and the second copolymer (B). Within the above range, the storage stability of the composition is maintained, and the film retention rate is enhanced.

If the second copolymer (B) comprises the repeat units (b2) and (b3) together, the total content of the repeat units (b2) and (b3) may be 10 to 50% by mole, 15 to 45% by mole, 15 to 35% by mole, 15 to 30% by mole, 20 to 30% by mole, 25 to 35% by mole, 22 to 35% by mole, or 25 to 30% by mole, based on the total number of moles of the repeat units constituting the second copolymer.

The molar ratio of the repeat units (b2):(b3) may be 50 to 99:50 to 1, 50 to 95:50 to 5, 50 to 90:50 to 10, 50 to 80:50 to 20, 50 to 70:50 to 30, 60 to 90:40 to 10, 70 to 90:30 to 10, or 60 to 80:40 to 20. Within the above range, it is possible to achieve excellent shelf-life at room temperature, thermal resistance, and chemical resistance, and the pattern formation is enhanced.

(b4) Repeat Unit Different from the Repeat Units (b1) to (b3)

The second copolymer (B) in the present invention may comprise a repeat unit (n4) different from the repeat units (b1) to (b3). The repeat unit (b4) may comprise one or more, two or more, or three or more.

The repeat unit (b4) may be derived from an ethylenically unsaturated compound different from the compounds described above.

For example, the ethylenically unsaturated compound may be an unsaturated carboxylic acid, an unsaturated carboxylic acid anhydride, an aromatic ring-containing unsaturated compound, an unsaturated carboxylic acid ester compound, an N-vinyl tertiary amine compound containing N-vinyl, an unsaturated ether compound, an unsaturated imide compound, or a mixture thereof. Examples of the unsaturated carboxylic acid and unsaturated carboxylic acid anhydride include an unsaturated monocarboxylic acid such as (meth)acrylic acid, crotonic acid, α-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; and an unsaturated polycarboxylic acid of trivalence or more and an anhydride thereof.

Examples of the ethylenically unsaturated compound containing an aromatic ring include phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tribromophenyl (meth)acrylate, styrene, methylstyrene, dimethylstyrene, trimethylstyrene, ethylstyrene, diethylstyrene, triethylstyrene, propylstyrene, butylstyrene, hexylstyrene, heptylstyrene, octylstyrene, fluorostyrene, chlorostyrene, bromostyrene, iodostyrene, methoxystyrene, ethoxystyrene, propoxystyrene, p-hydroxy-α-methylstyrene, acetylstyrene, vinyltoluene, divinylbenzene, vinylphenol, o-vinylbenzyl methyl ether, m-vinylbenzyl methyl ether, and p-vinylbenzyl methyl ether.

Examples of the unsaturated carboxylic acid ester compound include methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate.

Examples of the N-vinyl tertiary amine compound containing N-vinyl include N-vinyl pyrrolidone, N-vinyl carbazole, and N-vinyl morpholine.

Examples of the unsaturated ether compound include vinyl methyl ether and vinyl ethyl ether.

Examples of the unsaturated imide compound include N-phenylmaleimide, N-(4-chlorophenyl)maleimide, N-(4-hydroxyphenyl)maleimide, and N-cyclohexylmaleimide.

Specifically, the ethylenically unsaturated compound capable of deriving the repeat unit (b4) may be at least one unsaturated compound selected from the group consisting of an aromatic ring-containing unsaturated compound, an unsaturated carboxylic acid ester compound, and an unsaturated carboxylic acid.

According to an embodiment, the repeat (b4) may comprise a repeat unit (b4-a) derived from an aromatic ring-containing unsaturated compound and a repeat unit (b4-b) derived from an unsaturated carboxylic acid ester compound.

According to an embodiment, the repeat (b4) may comprise a repeat unit (b4-a) derived from an aromatic ring-containing unsaturated compound and a repeat unit (b4-c) derived from an unsaturated carboxylic acid.

According to an embodiment, the repeat (b4) may comprise a repeat unit (b4-a) derived from an aromatic ring-containing unsaturated compound, a repeat unit (b4-b) derived from an unsaturated carboxylic acid ester compound, and a repeat unit (b4-c) derived from an unsaturated carboxylic acid.

According to an embodiment, the repeat unit (b4) may be derived from an aromatic ring-containing unsaturated compound, in which case the content of the repeat unit (b4-a) derived from an aromatic ring-containing unsaturated compound may be 10 to 70/o by mole, 10 to 60% by mole, 20 to 60% by mole, 30 to 60% by mole, or 30 to 55% by mole, based on the total number of moles of the repeat units constituting the second copolymer (B).

According to an embodiment, the repeat unit (b4) may be derived from an unsaturated carboxylic acid ester compound, in which case the content of the repeat unit (b4-b) derived from an unsaturated carboxylic acid ester compound may be 10 to 30% by mole, 10 to 25% by mole, 15 to 30% by mole, or 15 to 25% by mole, based on the total number of moles of the repeat units constituting the second copolymer (B).

According to an embodiment, the repeat unit (b4) may be derived from an unsaturated carboxylic acid, in which case the content of the repeat unit (b4-c) derived from an unsaturated carboxylic acid may be 1 to 30% by mole, 1 to 20% by mole, 5 to 20% by mole, 5 to 18% by mole, or 10 to 18% by mole, based on the total number of moles of the repeat units constituting the second copolymer (B).

The second copolymer (B) used in the present invention may be copolymerized by a known method. Specifically, the second copolymer (B) may be prepared by charging to a reactor a radical polymerization initiator, a solvent, and monomer compounds capable of deriving the above repeat units, followed by charging nitrogen thereto and slowly stirring the mixture for polymerization.

The radical polymerization initiator is not particularly limited and may be the same as that used in preparing the first copolymer (A).

The solvent may be any conventional solvent commonly used in the preparation of a copolymer and may include, for example, propylene glycol monomethyl ether acetate (PGMEA).

The second copolymer (B) may have a weight average molecular weight (Mw) of 4,000 to 20,000 Da, 4,000 to 15,000 Da, or 4,000 to 13,000 Da. Within the above range, the adhesiveness to a substrate is excellent, the physical and chemical properties are good, and the viscosity is maintained at a proper level.

In addition, the second copolymer (B) may have an acid value of 10 to 75 mg KOH/g, 10 to 50 mg KOH/g, 10 to 40 mg KOH/g, 10 to 30 mg KOH/g, 20 to 40 mg KOH/g, 20 to 30 mg KOH/g, 20 to 28 mg KOH/g, 23 to 28 mg KOH/g, or 25 to 28 mg KOH/g. Within the above range, the shelf-life of the photosensitive resin composition can be further enhanced.

The content of the second copolymer (B) may be 1 to 70% by weight, 5 to 65% by weight, 1 to 60% by weight, or 5 to 63% by weight, based on the total weight of the photosensitive resin composition on the basis of solids content. Within the above range, a pattern profile after development may be favorable, and such properties as film retention rate and chemical resistance may be enhanced.

The first copolymer (A) and the second copolymer (B) as described above may have a weight ratio of 10 to 90:90 to 10, 20 to 80:80 to 20, 25 to 75:75 to 25, or 25 to 50:75 to 50. Within the above range, the succinate group and epoxy group are present in the composition in appropriate amounts and ratio, it is possible to increase the reactivity of the composition, thereby enhancing the degree of curing, as well as to perform patterning thanks to the increased reactivity even though the degree of crosslinking is increased, resulting in excellent resolution. In addition, it is possible to enhance the chemical resistance to chemical solvents or cleaning solvents, whereby deformation of the cured film can be prevented.

(C) Photopolymerizable Compound

The photopolymerizable compound employed in the present invention is a compound that is polymerizable by the action of a photopolymerization initiator. It may include a monofunctional or multifunctional ester compound of acrylic acid or methacrylic acid having at least one ethylenically unsaturated group. It may preferably be a multifunctional compound having at least two or three functional groups from the viewpoint of chemical resistance.

The polymerizable compound may be at least one selected from the group consisting of ethylene glycol di(meth)acrylate, propylene glycol di(meth)acrylate, diethylene glycol di(meth)acrylate, triethylene glycol di(meth)acrylate, 1,6-hexanediol di(meth)acrylate, polyethylene glycol di(meth)acrylate, polypropylene glycol di(meth)acrylate, glycerin tri(meth)acrylate, trimethylolpropane tri(meth)acrylate, pentaerythritol tri(meth)acrylate, a monoester of pentaerythritol tri(meth)acrylate and succinic acid, pentaerythritol tetra(meth)acrylate, dipentaerythritol penta(meth)acrylate, dipentaerythritol hexa(meth)acrylate, a monoester of dipentaerythritol penta(meth)acrylate and succinic acid, caprolactone modified dipentaerythritol hexa(meth)acrylate, pentaerythritol triacrylate-hexamethylene diisocyanate (a reaction product of pentaerythritol triacrylate and hexamethylene diisocyanate), tripentaerythritol hepta(meth)acrylate, tripentaerythritol octa(meth)acrylate, bisphenol A epoxyacrylate, and ethylene glycol monomethyl ether acrylate, but it is not limited thereto.

In addition, it may include a multifunctional urethane acrylate compound obtained by reacting a compound having a straight-chain alkylene group and an alicyclic structure with two or more isocyanate groups and a compound having one or more hydroxyl groups and three, four, or five acryloyloxy groups and/or methacryloyloxy groups in the molecule, but it is not limited thereto.

Examples of the commercially available photopolymerizable compound include the following commercially available products.

First, examples of the monofunctional (meth)acrylate products include Aronix M-101, M-111, and M-114 manufactured by Toagosei, AKAYARAD TC-11 OS and TC-120S manufactured by Nippon Kayaku, and V-158 and V-2311 manufactured by Osaka Yuki Kayaku Kogyo.

Examples of the bifunctional (meth)acrylate products include Aronix M-210, M-240, and M-6200 manufactured by Toagosei, KAYARAD HDDA, HX-220, and R-604 manufactured by Nippon Kayaku, and V-260, V-312, and V-335 HP manufactured by Osaka Yuki Kayaku Kogyo.

Examples of the tri- and higher functional (meth)acrylate products include Aronix M-309, M-400, M-403, M-405, M-450, M-7100, M-8030, M-8060, and TO-1382 manufactured by Toagosei, KAYARAD TMPTA, DPHA, DPHA-40H, DPCA-20, DPCA-30, DPCA-60, and DPCA-120 manufactured by Nippon Kayaku, and V-295, V-300, V-360, V-GPT, V-3PA, and V-400 manufactured by Osaka Yuki Kayaku Kogyo.

The photopolymerizable compounds may be used alone or in combination of two or more thereof. It may be employed in an amount of 1 to 100 parts by weight, 10 to 80 parts by weight, 30 to 80 parts by weight, 30 to 70 parts by weight, 40 to 70 parts by weight, 50 to 70 parts by weight, or 60 to 70 parts by weight, based on 100 parts by weight of the first copolymer (A) and second copolymer (B) (hereinafter, copolymers) (on the basis of solids content). Within the above range, it is possible to achieve high sensitivity with excellent pattern developability and film characteristics.

(D) Photopolymerization Initiator

The photopolymerization initiator employed in the present invention serves to initiate the polymerization of monomers that can be cured by visible light, ultraviolet light, deep-ultraviolet radiation, or the like. The photopolymerization initiator may be a radical initiator. Examples thereof include at least one selected from the group consisting of an acetophenone-based, benzophenone-based, benzoin-based, benzoyl-based, xanthone-based, triazine-based, halomethyloxadiazole-based, and rofindimer-based photopolymerization initiators, but it is not limited thereto.

Particular examples thereof may include 2,2′-azobis(2,4-dimethylvaleronitrile), 2,2′-azobis(4-methoxy-2,4-dimethylvaleronitrile), benzoyl peroxide, lauryl peroxide, t-butyl peroxy pivalate, 1,1-bis(t-butylperoxy)cyclohexane, p-dimethylaminoacetophenone, 2-benzyl-2-(dimethylamino)-1-[4-(4-morpholinyl)phenyl]-1-butanone, 2-hydroxy-2-methyl-1-phenyl-propan-1-one, benzyl dimethyl ketal, benzophenone, benzoin propyl ether, diethyl thioxanthone, 2,4-bis (trichloromethyl)-6-p-methoxyphenyl-s-triazine, 2-trichloromethyl-5-styryl-1,3,4-oxodiazole, 9-phenylacridine, 3-methyl-5-amino-((s-triazin-2-yl)amino)-3-phenylcoumarin, 2-(o-chlorophenyl)-4,5-diphenylimidazolyl dimer, 1-phenyl-1,2-propanedione-2-(o-ethoxycarbonyl)oxime, 1-[4-(phenylthio)phenyl]-octane-1,2-dione-2-(o-benzoyloxime), o-enzoyl-4′-(benzmercapto)benzoyl-hexyl-ketoxime, 2,4,6-trimethylphenylcarbonyl-diphenylphosphonyloxide, a hexafluorophosphoro-trialkylphenylsulfonium salt, 2-mercaptobenzimidazole, 2,2′-benzothiazolyl disulfide, and a mixture thereof, but it is not limited thereto. In addition, the oxime-based compounds disclosed in KR 2004-0007700, KR 2005-0084149, KR 2008-0083650, KR 2008-0080208, KR 2007-0044062, KR 2007-0091110, KR 2007-0044753, KR 2009-0009991, KR 2009-0093933, KR 2010-0097658, KR 2011-0059525, WO 10102502, and WO 10133077 may be used.

The photopolymerization initiator may be employed in an amount of 1 to 20 parts by weight, 1 to 15 parts by weight, 1 to 10 parts by weight, 1 to 8 parts by weight, or 3 to 8 parts by weight, based on 100 parts by weight of the copolymers (on the basis of solids content). Within the above range, it is possible to achieve high sensitivity with excellent pattern developability and film characteristics.

(E) Solvent

The photosensitive resin composition of the present invention may preferably be prepared as a liquid composition in which the above components are mixed with a solvent.

The solvent should have good compatibility and miscibility with other components in the composition and should have storage stability when stored at room temperature and low temperatures. In addition, an appropriate amount of the solvent remains under the pre-bake temperature condition during coating to aid in film formation and leveling. In addition, the solvent should be sufficiently volatilized in the low-temperature curing condition to form a coating film. Further, the solvent may induce a reaction capable of exhibiting color when an adhesion supplement containing an isocyanate group, which will be described below, is used together with a binder and a solvent.

Examples of such solvents include ethylene glycol monoalkyl ether acetates such as ethylene glycol monomethyl ether acetate and ethylene glycol monoethyl ether acetate; propylene glycol monoalkyl ethers such as propylene glycol monomethyl ether, propylene glycol monoethyl ether, propylene glycol monopropyl ether, and propylene glycol monobutyl ether; propylene glycol dialkyl ethers such as propylene glycol dimethyl ether, propylene glycol diethyl ether, propylene glycol dipropyl ether, and propylene glycol dibutyl ether; dipropylene glycol dialkyl ethers such as dipropylene glycol dimethyl ether; propylene glycol monoalkyl ether acetates such as propylene glycol monomethyl ether acetate, propylene glycol monoethyl ether acetate, propylene glycol monopropyl ether acetate, and propylene glycol monobutyl ether acetate; cellosolves such as ethyl cellosolve and butyl cellosolve; carbitols such as butyl carbitol; lactic acid esters such as methyl lactic acid, ethyl lactic acid, n-propyl lactic acid, and isopropyl lactic acid; aliphatic carboxylic acid esters such as ethyl acetic acid, n-propyl acetic acid, isopropyl acetic acid, n-butyl acetic acid, isobutyl acetic acid, n-amyl acetic acid, isoamyl acetic acid, isopropyl propionic acid, n-butyl propionic acid, and isobutyl propionic acid; esters such as methyl 3-methoxypropionic acid, ethyl 3-methoxypropionic acid, methyl 3-ethoxypropionic acid, ethyl 3-ethoxypropionic acid, methyl pyruvic acid, and ethyl pyruvic acid; aromatic hydrocarbons such as toluene and xylene; ketones such as 2-heptanone, 3-heptanone, and 4-heptanone; amides such as N-dimethylformamide, N-methylacetamide, N,N-dimethylacetamide, and N-methylpyrrolidone; lactones such as γ-butyrolactone; and mixtures thereof. The solvent may be used alone or in combination of two or more. Preferably, the solvent may be propylene glycol monoalkyl ethers.

In addition, the solvent in the present invention may comprise a cyclic ketone-based compound.

The cyclic ketone-based compound has excellent compatibility with other components in the composition. In addition, since it has a low flash point and boiling point, it can be readily removed even at a low curing temperature, whereby a hard cured film can be formed. The solvent removal rate (evaporation rate) is fast, which contributes to the improvement in the curing rate.

Specifically, the cyclic ketone-based compound may be at least one selected from the group consisting of cyclobutanone, cyclopentanone, and cyclohexanone. It may preferably be cyclopentanone among them.

According to an embodiment, the solvent may be propylene glycol monoalkyl ethers.

According to an embodiment, the solvent may be a mixed solvent of a propylene glycol monoalkyl ether and a cyclic ketone-based compound. If the solvent is a mixed solvent, the weight ratio of the propylene glycol monoalkyl ether to the cyclic ketone-based compound may be 5 to 20:1, 5 to 15:1, or 8 to 15:1. In the photosensitive resin composition according to the present invention, the content of the solvent may be such that the solids content is 5 to 70% by weight, 10 to 55% by weight, or 15 to 35% by weight, based on the total weight of the composition, from the viewpoint of coatability, stability, and the like of the photosensitive resin composition.

(F) Adhesion Supplement

The photosensitive resin composition of the present invention may comprise an adhesion supplement to enhance the adhesiveness to a substrate.

The adhesion supplement may have at least one reactive group selected from the group consisting of a carboxyl group, a (meth)acryloyl group, an isocyanate group, an amino group, a mercapto group, a vinyl group, and an epoxy group. Preferably, it may have an isocyanate group.

Examples of the adhesion supplement include trimethoxysilyl benzoic acid, γ-methacryloxypropyltrimethoxysilane, vinyltriacetoxysilane, vinyltrimethoxysilane, γ-isocyanatopropyltriethoxysilane, γ-glycidoxypropyltrimethoxysilane, γ-glycidoxypropyltriethoxysilane, N-phenylaminopropyltrimethoxysilane, β-(3,4-epoxycyclohexyl)ethyltrimethoxysilane, 3-isocyanate propyltrimethoxysilane, 3-isocyanate propyltriethoxysilane, and a mixture thereof.

Preferably, it may be γ-glycidoxypropyltriethoxysilane, γ-glycidoxypropyltrimethoxysilane, 3-isocyanate propyltrimethoxysilane, 3-isocyanate propyltriethoxysilane, or N-phenylaminopropyltrimethoxysilane. More preferably, it may be 3-isocyanatopropyltrimethoxysilane, 3-isocyanatepropyltriethoxysilane, or a mixture thereof, which is an adhesion supplement containing an isocyanate group.

The content of the adhesion supplement may be 0.001 to 5 parts by weight, 0.01 to 5 parts by weight, 0.01 to 4 parts by weight, 0.1 to 4 parts by weight, 1 to 4 parts by weight, or 1 to 3 parts by weight, based on 100 parts by weight of the copolymers (on the basis of solids content). Within the above range, the adhesiveness to a substrate may be further enhanced.

(G) Surfactant

The photosensitive resin composition of the present invention, if necessary, may further comprise a surfactant in order to enhance the coatability and to prevent the generation of defects.

The kind of surfactant is not particularly limited. Preferably, it may include fluorine-based surfactants, silicone-based surfactants, non-ionic surfactants, and the like.

Examples of the fluorine- and silicon-based surfactants include BM-1000 and BM-1100 manufactured by BM CHEMIE, Megapack F-142 D, Megapack F-172, Megapack F-173, and Megapack F-183, F-470, F-471, F-475, F-482, and F-489 manufactured by Dai Nippon Ink Chemical Kogyo, Florad FC-135, Florad FC-170 C, Florad FC-430, and Florad FC-431 manufactured by Sumitomo 3M, Sufron S-112, Sufron S-113, Sufron S-131, Sufron S-141, Sufron S-145, Sufron S-382, Sufron SC-101, Sufron SC-102, Sufron SC-103, Sufron SC-104, Sufron SC-105, and Sufron SC-106 manufactured by Asahi Glass, Efiop EF301, Eftop EF303, and Eftop EF352 manufactured by Shinakida Kasei, SH-28 PA, SH-190, SH-193, SZ-6032, SF-8428, DC-57, and DC-190 manufactured by Toray Silicon, DC3PA, DC7PA, SH1IPA, SH21PA, SH8400, FZ-2100, FZ-2110, FZ-2122, FZ-2222, and FZ-2233 manufactured by Dow Corning Toray Silicon, TSF-4440, TSF-4300, TSF-4445, TSF-4446, TSF-4460, and TSF-4452 manufactured by GE Toshiba Silicon, and BYK-307 and BYK-333 manufactured by BYK.

Examples of the non-ionic surfactants include polyoxyethylene alkyl ethers such as polyoxyethylene lauryl ether, polyoxyethylene stearyl ether, polyoxyethylene oleyl ether, and the like; polyoxyethylene aryl ethers such as polyoxyethylene octylphenyl ether, polyoxyethylene nonylphenyl ether, and the like; and polyoxyethylene dialkyl esters such as polyoxyethylene dilaurate, polyoxyethylene distearate, and the like.

Examples of other surfactants include organosiloxane polymer KP341 (manufactured by Shin-Etsu Chemical Co., Ltd.), (meth)acrylate-based copolymer Polyflow Nos. 57 and 95 (manufactured by Kyoei Yuji Chemical Co., Ltd.), and the like. Preferably, BYK 333 from BYK among the above may be employed from the viewpoint of dispersibility. They may be used alone or in combination of two or more thereof.

The surfactant may be employed in an amount of 0.001 to 5 parts by weight, 0.01 to 3 parts by weight, or 0.1 to 3 parts by weight, based on 100 parts by weight of the copolymers (on the basis of solids content). Within the above range, the coating of the composition is smoothly carried out.

In addition, the photosensitive resin composition of the present invention may comprise other additives such as an antioxidant and a stabilizer as long as the physical properties of the colored photosensitive resin composition are not adversely affected.

The present invention provides a cured film formed from the photosensitive resin composition.

Specifically, the photosensitive resin composition according to the present invention may be coated on a substrate and then cured to prepare a cured film. In such an event, the cured film may be obtained by post-baking the photosensitive resin composition at a temperature of 150° C. or lower, 50 to 150° C., 50 to 130° C., 70 to 150° C., or 70 to 130° C.

Specifically, the cured film may be prepared by a method known in the art. For example, the photosensitive resin composition is coated on a silicon substrate or a glass substrate by a spin coating method, which is subjected to pre-bake at a temperature of 50° C. to 150° C. for 30 seconds to 130 seconds to remove solvents. It is then exposed to light using a photomask having a desired pattern and subjected to development using a developer (for example, a tetramethylammonium hydroxide (TMAH) solution) to form a pattern on the coating layer. Thereafter, the patterned coating layer is subjected to post-bake at a temperature of 150° C. or less, 50 to 150° C., 50 to 130° C., 70 to 150° C., or 70 to 130° C., for 10 minutes to 5 hours to prepare a desired cured film.

The exposure to light may be carried out at an exposure dose of 10 to 100 mJ/cm² in a wavelength band of 200 nm to 450 nm.

As described above, the first copolymer composed of a combination of specific structural units and the second copolymer composed of a combination of repeat units represented by specific chemical formulae are used as a binder in the photosensitive resin composition of the present invention to introduce appropriate amounts of a succinate group and an epoxy group to the composition. Thus, it is possible to prepare a cured film that can be sufficiently cured even at low temperatures by enhancing the degree of curing and that has excellent pattern forming capability and resolution through the control of the developability and enhancements in the crosslinking reaction. Further, since the composition can form a cured film having excellent chemical resistance to various chemical solvents, it can be advantageously applied to a device comprising a touch panel.

Hereinafter, the present invention will be described in more detail with reference to the following examples. However, these examples are provided to illustrate the present invention, and the scope of the present invention is not limited thereto only.

In the following synthesis examples, the weight average molecular weight is determined by gel permeation chromatography (GPC, eluent: tetrahydrofuran) referenced to a polystyrene standard.

### Embodiments for Carrying Out the Invention

Hereinafter, the present invention will be described in more detail with reference to examples. The following examples are merely illustrative of the present invention, and the scope of the present invention is not limited thereto.

### Preparation Example 1: Preparation of a First Copolymer (A)

A 500-ml, round-bottomed flask equipped with a refluxing condenser and a stirrer was charged with 40 g of a monomer mixture consisting of 50% by mole of styrene, 22% by mole of methacrylic acid, 10% by mole of glycidyl methacrylate, and 18% by mole of 3,4-epoxycyclohexylmethyl methacrylate, along with 120 g of methyl 3-methoxypropionate (MMP) as a solvent and 2 g of 2,2′-azobis(2,4-dimethylvaleronitrile) as a photopolymerization initiator. Thereafter, the mixture was heated to 70° C. and stirred for 8 hours to obtain a copolymer (A) having a solids content of 33% by weight. The copolymer thus prepared had a weight average molecular weight of 7,000 Da, a polydispersity (Mw/Mn) of 2.50, and an acid value of 24 mg KOH/g.

### Preparation Example 2: Preparation of a Second Copolymer (B-1)

A 250-ml, round-bottomed flask equipped with a refluxing condenser and a stirrer in a nitrogen atmosphere was charged with a monomer mixture composed of 50% by mole (24.58 g) of styrene, 17% by mole (6.91 g) of methyl methacrylate, 5% by mole (5.12 g) of 2-acryloyloxyethyl succinate, 10% by mole (6.71 g) of glycidyl methacrylate, and 18% by mole (16.68 g) of 3,4-epoxycyclohexylmethyl methacrylate, along with 5% by mole (5.74 g) of V-65 as a radical polymerization initiator, dissolved in 100 g of propylene glycol monomethyl ether acetate (PGMEA). Thereafter, the liquid mixture was heated to 65° C. and polymerized for 5 hours to obtain a copolymer B-1 having a solids content of 29.42% by weight. The copolymer B-1 thus prepared had a weight average molecular weight of 5,000 Da, a polydispersity (Mw/Mn) of 2.20, and an acid value of 27 mg KOH/g.

### Preparation Examples 3 and 4: Preparation of Second Copolymers B-2 and B-3

Second copolymers B-2 and B-3 were prepared in the same manner as in Preparation Example 2, except that the kinds and/or contents of the substances were changed as shown in Table 1 below.

TABLE 1

| | | | | | | | Weight average | | Acid value |
|---|---|---|---|---|---|---|---|---|---|
| | | | CH- | | | | molecular weight | Polydispersity | (mg |
| | Sty | GMA | epoxy | MAA | MMA | MAS | (Mw) (Da) | (Mw/Mn) | KOH/g) |
| Prep. Ex. 1 | 50 | 10 | 18 | 22 | — | — | 7,000 | 2.50 | 24 |
| Prep. Ex. 2 | 50 | 10 | 18 | — | 17 | 5 | 5,000 | 2.20 | 27 |
| Prep. Ex. 3 | 45 | — | 20 | 12 | 15 | 8 | 4,400 | 1.87 | 26 |
| Prep. Ex. 4 | 45 | — | 13 | 15 | 15 | 12 | 4,300 | 1.97 | 25 |

Styrene: Sty (corresponding to repeat units a4 or b4)
Glycidyl methacrylate: GMA (corresponding to repeat units a3 or b3)
3,4-epoxycyclohexylmethyl methacrylate: CH-epoxy (corresponding to repeat units a2 or b2)
Methacrylic acid: MAA (corresponding to repeat units a1 or b4)
Methyl methacrylate: MMA (corresponding to repeat unit b4)
2-acryloyloxyethyl succinate: MAS (corresponding to repeat unit b1)

### Examples and Comparative Examples: Preparation of Photosensitive Resin Compositions

The components used in the following Examples and Comparative Examples are as follows.

TABLE 2

| | | | Solids content | |
|---|---|---|---|---|
| Component | | | (wt %) | Manufacturer |
| First copolymer (A) | | Preparation Example 1 | 33 | — |
| Second | B-1 | Preparation Example 2 | 29.42 | — |
| copolymer (B) | B-2 | Preparation Example 3 | 28.40 | — |
| | B-3 | Preparation Example 4 | 28.95 | — |
| Photopolymerizable | | Dipentaerythritol hexaacrylate (DPHA) | 100 | Nippon Kayaku |
| compound (C) | | | | |
| Photopolymerization | | OXE-02 | 100 | BASF |
| initiator (D) | | | | |
| Adhesion supplement (F) | | 3-isocyanate propyltrietboxysilane KBE-9007N | 100 | Shinetsu |
| Surfactant (G) | | BYK-307 | 100 | BYK |
| Solvent (E) | E-1 | Propylene glycol monomethyl ether acetate (PGMEA) | — | Chemtronics |
| | E-2 | Cyclopentanone | — | Sigma Aldrich |

### Example 1

50 parts by weight of the first copolymer (A) of Preparation Example 1, 50 parts by weight of the second copolymer (B-1) of Preparation Example 2, 67 parts by weight of DPHA as a photopolymerizable compound (C), 5 parts by weight of the oxime-based photoinitiator OXE-02 as a photoinitiator (D), 2.6 parts by weight of KBE-9007N as an adhesion supplement (F), and 1.7 parts by weight of BYK-307 as a surfactant (G) were homogeneously mixed. Here, the respective contents are those based on the solids content exclusive of solvents. The mixture was dissolved in a mixed solvent composed of 611 parts by weight of PGMEA and 53 parts by weight of cyclopentanone such that the solids content of the mixture was 21% by weight. The resultant was mixed using a shaker for 2 hours to prepare a liquid-phase photosensitive resin composition.

### Examples 2 to 10 and Comparative Examples 1 and 2

Photosensitive resin compositions were each prepared in the same manner as in Example 1, except that the kinds and/or contents of the respective components were changed as shown in Tables 3 and 4 below.

TABLE 3

| | First copolymer | Second copolymer (B) | | |
|---|---|---|---|---|
| (Part by weight) | (A) | B-1 | B-2 | B-3 |
| Example 1 | 50 | 50 | — | — |
| Example 2 | 75 | — | 25 | — |
| Example 3 | 50 | — | 50 | — |
| Example 4 | 25 | — | 75 | — |
| Example 5 | 75 | — | — | 25 |
| Example 6 | 50 | — | — | 50 |
| Example 7 | 50 | 50 | — | — |
| Example 8 | 75 | — | 25 | — |
| Example 9 | 50 | — | 50 | — |
| Example 10 | 25 | — | 75 | — |
| Comparative Example 1 | 100 | — | — | — |
| Comparative Example 2 | 100 | — | — | — |

TABLE 4

| (Part by | Photopolymerizable | Photopolymerization | Adhesion | Surfactant | Solvent (E) | |
|---|---|---|---|---|---|---|
| weight) | compound (C) | initiator (D) | supplement (F) | (G) | E-1 | E-2 |
| Ex. 1 | 67 | 5 | 2.6 | 1.7 | 611 | 53 |
| Ex. 2 | 67 | 5 | 2.6 | 1.7 | 611 | 53 |
| Ex. 3 | 67 | 5 | 2.6 | 1.7 | 611 | 53 |
| Ex. 4 | 67 | 5 | 2.6 | 1.7 | 611 | 53 |
| Ex. 5 | 67 | 5 | 2.6 | 1.7 | 611 | 53 |
| Ex. 6 | 67 | 5 | 2.6 | 1.7 | 611 | 53 |
| Ex. 7 | 67 | 5 | 2.6 | 1.7 | 664 | — |
| Ex. 8 | 67 | 5 | 2.6 | 1.7 | 664 | — |
| Ex. 9 | 67 | 5 | 2.6 | 1.7 | 664 | — |
| Ex. 10 | 67 | 5 | 2.6 | 1.7 | 664 | — |
| C. Ex. 1 | 67 | 5 | 2.6 | 1.7 | 611 | 53 |
| C. Ex. 2 | 67 | 5 | 2.6 | 1.7 | 664 | — |

### Evaluation Example

Preparation of a Cured Film from a Photosensitive Resin Composition

The photosensitive resin compositions obtained in the Examples and Comparative Examples were each coated on a glass substrate using a spin coater and pre-baked at 100° C. for 60 seconds to form a coated film having a thickness of 2.7±0.2 μm. A mask was placed on the coated film thus formed such that an area of 5 cm by 5 cm of the coated film was 100% exposed to light and that the gap with the substrate was maintained at 25 μm. Thereafter, the film was exposed to light at an exposure dose of 30 mJ/cm² based on a wavelength of 365 nm for a certain time period using an aligner (model name: MA6) that emits light having a wavelength of 200 nm to 450 nm. It was then developed with an aqueous developer of 2.38% by weight of TMAH at 23° C. until the unexposed portion was completely washed out. The pattern thus formed was post-baked in an oven at 130° C. for 1 hour to obtain a cured film.

### Evaluation Example 1: Chemical Resistance (Acetone)

According to the preparation method of a cured film, the compositions obtained in the Examples and Comparative Examples were each coated on a glass substrate and then pre-baked. Thereafter, a mask prepared to allow exposure of 35 square-shaped patterns with a size of 50 μm×50 μm was applied, followed by exposure and development. The developed film was heated in a convection oven at 130° C. for 60 minutes to obtain a cured film. Thereafter, the pattern of the cured film was wiped 90 times at a constant force and speed using a wipe moistened with acetone. Then, the degree of dissolution of the 35 square patterns was observed, and the chemical resistance was evaluated according to the following evaluation criteria.

[Evaluation Criteria]

∘: not dissolved at all

Δ: 10% or less of the total number of patterns dissolved

x: greater than 10% of the total number of patterns dissolved

### Evaluation Example 2: Chemical Resistance (Organic and Aqueous Strippers)

According to the preparation method of a cured film, the compositions obtained in the Examples and Comparative Examples were each coated on a glass substrate and then subjected to pre-bake, exposure, and development. The developed film was heated in a convection oven at 130° C. for 60 minutes to obtain a cured film. The cured film was immersed in an organic stripper TOK-106 (MEA 60-80% and DMSO 20-40%) and/or an aqueous stripper LT-360 (alcohol 15-30%, ether 25-45%, amine 1-10%, pyrrolidone 1-30%, and DI 10-50%) at 50° C. for 1 minute and then taken out. The types of strippers used in the Examples and Comparative Examples are shown in Table 5 below. Thereafter, the thickness of the film was measured with a non-contact-type thickness meter (SIS-2000, SNU), and the thickness change rate was calculated according to the following equation. In addition, the thickness change rate for 3-minute immersion was measured in the same manner except that the cured film was immersed in the organic stripper for 3 minutes. The thickness change rates for 1-minute immersion and 3-minute immersion were measured, respectively, and the chemical resistance was evaluated according to the following evaluation criteria.

Thickness change rate (%)=(thickness after immersion in the stripper/thickness before immersion in the stripper)×100 [Equation]

[Evaluation Criteria]

Good (⊚): 0≤thickness change rate (%) for 3-minute immersion—thickness change rate (%) for 1-minute immersion

Normal (∘): −2<thickness change rate (%) for 3-minute immersion—thickness change rate (%) for 1-minute immersion<0

Poor (x): thickness change rate (%) for 3-minute immersion—thickness change rate (%) for 1-minute immersion 5-2

### Evaluation Example 3: Resolution (Litho Performance)

The photosensitive resin composition solutions prepared in the Examples and Comparative Examples were each uniformly coated onto a glass substrate by spin coating, which was then dried on a hot plate kept at 100° C. for 1 minute to prepare a substrate on which a dry film having a thickness of 2.7±0.2 μm was formed. A negative mask having an opening pattern with a line width of 25 μm was placed on the substrate on which the dry film was formed. It was then exposed to light at an exposure dose of 30 mJ/cm² using an aligner (model name: MA6) and developed with an aqueous solution diluted to 2.38% by weight of TMAH at 23° C. until the unexposed portion was completely washed out. Thereafter, the patterned exposure film was post-baked in an oven at 130° C. for 1 hour to obtain a cured film. For the substrate on which the cured film was formed, the line width of the bottom of the pattern was measured with a non-contact type thickness meter (SIS-2000, SNU), and the resolution was evaluated according to the following evaluation criteria.

[Evaluation Criteria]

OK: Bottom line was formed to be 2 μm or more

NG: Bottom line could not be measured

TABLE 5

| | Chemical | | | |
|---|---|---|---|---|
| | resistance | Chemical resistance (stripper) | | |
| | (acetone) | Stripper | Stripper type | Resolution |
| Ex. 1 | ∘ | ∘ | Organic | OK |
| Ex. 2 | ∘ | ∘ | Organic | OK |
| Ex. 3 | ∘ | ⊚ | Organic | OK |
| Ex. 4 | ∘ | ⊚ | Organic | OK |
| Ex. 5 | Δ | ⊚ | Organic | OK |
| Ex. 6 | ∘ | ⊚ | Organic | OK |
| Ex. 7 | ∘ | ∘ | Aqueous | OK |
| Ex. 8 | Δ | ∘ | Aqueous | OK |
| Ex. 9 | Δ | ∘ | Aqueous | OK |
| Ex. 10 | ∘ | ∘ | Aqueous | OK |
| C. Ex. 1 | x | x | Organic or aqueous | OK |
| C. Ex. 2 | x | ∘ | Aqueous | NG |

Referring to the results in Table 5, all of the cured films formed from the photosensitive resin compositions of Examples 1 to 10 had excellent chemical resistance and showed excellent resolution without delamination of a pattern. In contrast, the cured films formed from the photosensitive resin compositions of Comparative Examples 1 and 2 were had poor chemical resistance, and defects such as protrusions were observed in the pattern, resulting in a worse resolution than that of the Examples.

1. A photosensitive resin composition, which comprises (A) a first copolymer comprising (a1) a structural unit derived from an ethylenically unsaturated carboxylic acid, an ethylenically unsaturated carboxylic anhydride, or a combination thereof; (a2) a structural unit derived from an ethylenically unsaturated compound containing an alicyclic epoxy group; (a3) a structural unit derived from an ethylenically unsaturated compound containing an acyclic epoxy group; and (a4) a structural unit derived from an ethylenically unsaturated compound different from (a1) to (a3);
(B) a second copolymer comprising (b1) a repeat unit represented by the following Formula 1 and comprising at least one selected from the group consisting of (b2) a repeat unit represented by the following Formula 2, (b3) a repeat unit represented by the following Formula 3, and (b4) a repeat unit different from the repeat units (b1) to (b3);
(C) a photopolymerizable compound;
(D) a photopolymerization initiator; and
(E) a solvent: 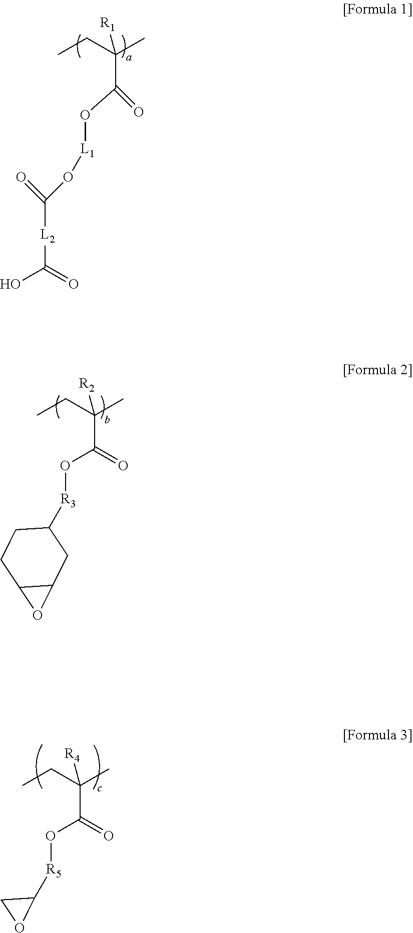
in the above formulae,
R₁ is hydrogen or substituted or unsubstituted C₁₋₂₀ alkyl,
Lᵢ and L₂ are each independently a substituted or unsubstituted C₁₋₁₀ alkylene or a substituted or unsubstituted C₆₋₂₀ arylene,
R₂ and R₄ are each independently hydrogen or C₁₋₈ alkyl,
R₃ and R₅ are each independently C₁₋₄ alkylene, and
a, b, and c are each independently an integer of 1 to 100.

2. The photosensitive resin composition of claim 1, wherein the first copolymer (A) and the second copolymer (B) have a weight ratio of 10 to 90:90 to 10.

3. The photosensitive resin composition of claim 1, wherein the second copolymer (B) has a weight average molecular weight of 4,000 to 15,000 Da and an acid value of 10 to 75 mg KOH/g.

4. The photosensitive resin composition of claim 1, wherein the content of the repeat unit (b1) is 1 to 15% by weight based on the total weight of the first copolymer (A) and the second copolymer (B).

5. The photosensitive resin composition of claim 1, wherein the content of the repeat unit (b1) is 3 to 20% by mole based on the total number of moles of the repeat units constituting the second copolymer (B).

6. The photosensitive resin composition of claim 1, wherein the contents of the repeat unit (b2) and the repeat unit (b3) are 10 to 30% by mole based on the total number of moles of the repeat units constituting the second copolymer (B), respectively.

7. The photosensitive resin composition of claim 1, wherein the repeat unit (b4) is derived from an ethylenically unsaturated compound, and the ethylenically unsaturated compound comprises at least one selected from the group consisting of an aromatic ring-containing unsaturated compound, an unsaturated carboxylic acid ester compound, and an unsaturated carboxylic acid.

8. The photosensitive resin composition of claim 7, wherein the repeat (b4) comprises a repeat unit (b4-a) derived from an aromatic ring-containing unsaturated compound and a repeat unit (b4-b) derived from an unsaturated carboxylic acid ester compound.

9. The photosensitive resin composition of claim 7, wherein the repeat (b4) comprises a repeat unit (b4-a) derived from an aromatic ring-containing unsaturated compound, a repeat unit (b4-b) derived from an unsaturated carboxylic acid ester compound, and a repeat unit (b4-c) derived from an unsaturated carboxylic acid.

10. The photosensitive resin composition of claim 7, wherein the repeat unit (b4) is derived from the aromatic ring-containing unsaturated compound, and the content of the repeat unit (b4) is 10 to 60% by mole based on the total number of moles of the repeat units constituting the second copolymer (B).

11. The photosensitive resin composition of claim 7, wherein the repeat unit (b4) is derived from the unsaturated carboxylic acid ester compound, and the content of the repeat unit (b4) is 10 to 30% by mole based on the total number of moles of the repeat units constituting the second copolymer (B).

12. The photosensitive resin composition of claim 7, wherein the repeat unit (b4) is derived from the unsaturated carboxylic acid, and the content of the repeat unit (b4) is 1 to 30% by mole based on the total number of moles of the repeat units constituting the second copolymer (B).

13. The photosensitive resin composition of claim 1, which comprises the second copolymer (B) in an amount of 1 to 70% by weight based on the total weight of the photosensitive resin composition on the basis of solids content.

14. The photosensitive resin composition of claim 1, wherein the solvent (D) comprises a cyclic ketone-based compound.

15. The photosensitive resin composition of claim 14, wherein the cyclic ketone-based compound is at least one selected from the group consisting of cyclobutanone, cyclopentanone, and cyclohexanone.

16. A cured film prepared from the photosensitive resin composition of claim 1.

17. The cured film of claim 16, which is obtained by post-baking the photosensitive resin composition at a temperature of 70 to 150° C.
